(19) United States
(12) Patent Application Publication
(10) Pub. No.: US 2021/0332295 A1
(43) Pub. Date: Oct. 28, 2021

(54) WHITE LIGHT QUANTUM DOT LIGHT EMITTING DIODE DEVICE AND PREPARATION METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Yuanchun WU, Shenzhen (CN); Shibo JIAO, Shenzhen (CN); Wei YUAN, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/619,638

(22) PCT Filed: Oct. 23, 2019
(86) PCT No.: PCT/CN2019/112640

§ 371 Date: Dec. 5, 2019

(30) Foreign Application Priority Data
Aug. 29, 2019 (CN) 201910805626.2

(51) Int. Cl. C09K 11/88; C09K 11/56; C09K 11/66

(52) U.S. Cl. CPC C09K 11/883; B82Y 20/00; C09K 11/661; C09K 11/565

(57) ABSTRACT

A white light quantum dot light emitting diode device, including: a substrate; an anode layer formed on the substrate; a hole injection layer formed on the anode layer; a hole transport layer formed on the hole injection layer; a plurality of quantum dot layers formed on the hole injection layer, wherein the plurality of quantum dot layers includes a blue quantum dot layer, a green quantum dot layer, and a red light quantum dot layer; a plurality of isolation layers, each of the isolation layers is formed between any two of the plurality of quantum dot layers; an electron transport layer formed on the plurality of quantum dot layers; and a cathode layer formed on the electron transport layer.

### FIELD OF INVENTION

The present invention relates to the field of display technology, and in particular, to a white light quantum dot light emitting diode device and a method of preparing the same.

### BACKGROUND OF INVENTION

Quantum dots have a narrow emission spectrum half-width, and their spectral ranges shift as the quantum dot sizes change, consequently, a quantum dot light emitting diode (QD-LED) device not only has high luminous efficiency, but its light emitting range can encompass an entire visible spectral range. Therefore, in recent years, researches of the QD-LED devices have attracted extensive attention.

### Technical Problem

The performance of current quantum dot light emitting diodes is relatively low compared to monochromatic light quantum dot light emitting diodes. For example, in a case of adopting a stacked quantum dot luminescent layer, an upper quantum dots will dissolve or penetrate the underlying quantum dots. At present, improving performance of the quantum dot light emitting diodes is mainly achieved by optimizing quantum efficiency of the quantum dots, which is difficult and costly.

### SUMMARY OF INVENTION

In order to solve the above problems, the present invention provides a white light quantum dot light emitting diode device, including: a substrate; an anode layer formed on the substrate; a hole injection layer formed on the anode layer; a hole transport layer formed on the hole injection layer; a plurality of quantum dot layers formed on the hole injection layer, wherein the plurality of quantum dot layers includes a blue quantum dot layer, a green quantum dot layer, and a red light quantum dot layer; a plurality of isolation layers, each of the isolation layers being formed between any two of the plurality of quantum dot layers; an electron transport layer formed on the plurality of quantum dot layers; and a cathode layer formed on the electron transport layer.

Preferably, the substrate is a glass substrate.

Preferably, the hole injection layer has a thickness of 10 nm; the hole transport layer has a thickness of 30 nm; and the electron transport layer has a thickness of 50 nm.

Preferably, the blue quantum dot layer, the green quantum dot layer and the red light quantum dot layer have a thickness of 30 nm.

Preferably, the isolation layer is composed of zinc oxide (ZnO) or titanium dioxide (TiO₂) or tin dioxide (SnO₂) particles.

Preferably, the isolation layer is a single layer structure having a thickness ranging from 1 nm to 10 nm.

Preferably, the quantum dots are a core-shell structure.

Preferably, the core structure is composed of at least one of cadmium sulfide, cadmium selenide, cadmium telluride, lead sulfide, and lead selenide; and the shell structure is composed of zinc sulfide or zinc selenide.

The invention also provide a method for preparing a white light quantum dot light emitting diode device, including: providing a glass substrate on which an anode layer is formed; forming a hole injection layer on the anode layer; forming a hole transport layer on the hole injection layer; forming a plurality of quantum dot layers and a plurality of isolation layers comprising a blue quantum dot layer, a first isolation layer, a green light quantum dot layer, a second isolation layer, and a red light quantum dot layer on the hole transport layer; forming an electron transport layer on the plurality of quantum dot layers; and forming a cathode layer on the electron transport layer.

Preferably, the isolation layer is formed by any one of spin coating, inkjet, and electroplating.

The present invention further provides another white light quantum dot light emitting diode device, including: a substrate; an anode layer formed on the substrate; a hole injection layer having a thickness of 10 nm formed on the anode layer; a hole transport layer having a thickness of 30 nm formed on the hole injection layer; a plurality of quantum dot layers formed on the hole injection layer, wherein the plurality of quantum dot layers includes a blue quantum dot layer, a green quantum dot layer, and a red light quantum dot layer; a plurality of isolation layers, each of the isolation layers being formed between any two of the plurality of quantum dot layers; an electron transport layer having a thickness of 50 nm formed on the plurality of quantum dot layers; and a cathode layer formed on the electron transport layer.

Preferably, the substrate is a glass substrate.

Preferably, the isolation layer is composed of zinc oxide (ZnO) or titanium dioxide (TiO₂) or tin dioxide (SnO₂) particles.

Preferably, the isolation layer is a single layer structure having a thickness ranging from 1 nm to 10 nm.

Preferably, the quantum dots are a core-shell structure.

Preferably, the core structure is composed of at least one of cadmium sulfide, cadmium selenide, cadmium telluride, lead sulfide, and lead selenide; and the shell structure is composed of zinc sulfide or zinc selenide.

### BENEFICIAL EFFECT

The white light quantum dot light emitting diode device of the invention is provided with a nano-sized isolation layer between the plurality of quantum dot layers. Preventing the interpenetration of the quantum dots and the dissolution between different quantum dot layers, thereby improving device performance.

### DESCRIPTION OF DRAWINGS

FIG. 1 is a schematic structural view of a white light quantum dot light emitting diode device according to an embodiment of the present invention.

FIG. 2 is a flow chart of a method for preparing a white light quantum dot light emitting diode device according to an embodiment of the present invention.

FIG. 3 is a schematic view showing a core-shell structure of a quantum dot according to an embodiment of the present invention.

FIG. 4 is a light emission spectrum of a white light quantum dot light emitting diode device according to an embodiment of the present invention.

### DETAILED DESCRIPTION OF PREFERRED EMBODIMENTS

The technical solutions in the embodiments of the present invention will be clearly and completely described in the following with reference to the accompanying drawings. It is obvious that the described embodiments are only a part of the embodiments of the invention, and not all of the embodiments. All other embodiments obtained by a person skilled in the art based on the embodiments of the present invention without creative efforts are within the scope of the present application.

The following description of the embodiments is provided to illustrate the specific embodiments of the invention. Directional terminologies mentioned in the application, such as “above”, “under”, “front”, “back”, “left”, “right”, “inside”, “outside”, “side”, etc., are only refer to the directions of the accompanying drawings. Therefore, the directional terminology used is for the purpose of illustration and understanding of the invention.

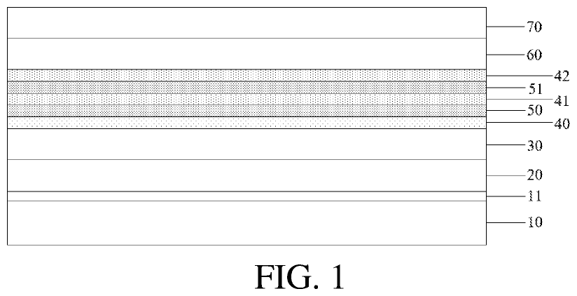

FIG. 1 is a schematic structural diagram of a white light quantum dot light emitting diode device according to an embodiment of the present invention, including: a substrate 10; an anode layer 11 formed on the substrate 10; a hole injection layer 20 formed on the anode layer 11; a hole transport layer 30 formed on the hole injection layer 20; a plurality of quantum dot layers formed on the hole injection layer 20, wherein the plurality of quantum dot layers and the plurality of isolation layers include a blue quantum dot layer 40, a first isolation layer 50, a green quantum dot layer 41, a second isolation layer 51, and a red light quantum dot layer 42; an electron transport layer 60 formed on the plurality of quantum dot layers; and a cathode layer 70 formed on the electron transport layer 60.

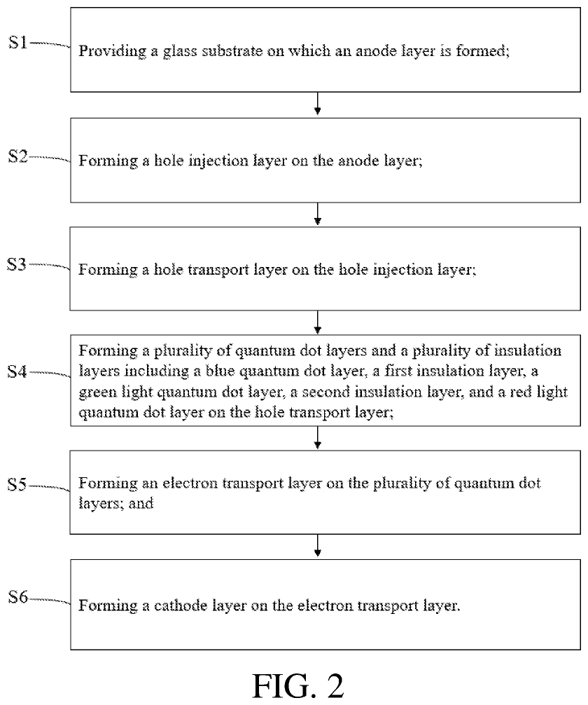

FIG. 2 is a flow chart of a method for preparing a white light quantum dot light emitting diode device according to an embodiment of the present invention. In a preferred embodiment of the present invention, the process includes: S1, providing a glass substrate coated with an indium tin oxide (ITO) film as an anode layer; S2, spin-coating a hole injection layer solution on the anode layer and sintering at 150 degrees Celsius for 20 minutes under nitrogen atmosphere to form a hole injection layer, and the hole injection layer solution may be, for example, a polythiophene solution; S3, spin-coating a hole transport layer solution on the hole injection layer, and sintering at 150 degrees Celsius for 20 minutes under nitrogen atmosphere to form a hole transport layer, and the hole transport layer solution may be, for example, a triarylamine polymer solution; S4, spin-coating a blue quantum dot solution with a concentration of 10 mg/ml on the hole transport layer, and sintering at 150 degrees Celsius for 20 minutes under nitrogen atmosphere to form a blue quantum dot layer; Next, spin-coating a zinc oxide (ZnO) solution on the blue quantum dot layer, and the ZnO solution is dissolved with nano-sized ZnO particles, and the concentration of the ZnO solution is 5 mg/ml, the spin-coating rate is 4000 rpm/min, and the spin-coating time is 30-40 seconds, then drying at a temperature of 100-200 degrees Celsius to form a single-layer structure of a first isolation layer having a thickness ranging from 1 nm to 10 nm; Following, repeat the above processes to sequentially form a green light quantum dot layer, a second isolation layer, and a red light quantum dot layer; S5, spin-coating an electron transport layer solution on the quantum dot layer, and sintering at 150 degrees Celsius for 20 minutes under nitrogen atmosphere to form an electron transport layer, and the electron transport layer solution may be, for example, a 1,3,5-tris(3-(3-pyridyl)phenyl)benzene solution; and S6, depositing an aluminum metal film as a cathode layer on the electron transport layer by evaporation.

In another preferred embodiment of the present invention, the process includes: S1, providing a glass substrate coated with an indium tin oxide (ITO) film as an anode layer; S2, dispensing a hole injection layer solution on the anode layer and sintering at 150 degrees Celsius for 20 minutes under nitrogen atmosphere to form a hole injection layer, and the hole injection layer solution may be, for example, a polythiophene solution; S3, dispensing a hole transport layer solution on the hole injection layer by an inkjet method, and sintering at 150 degrees Celsius for 20 minutes under nitrogen atmosphere to form a hole transport layer, and the hole transport layer solution may be, for example, a triarylamine polymer solution; S4, dispensing a blue quantum dot solution with a concentration of 10 mg/ml on the hole transport layer by an inkjet method, and sintering at 150 degrees Celsius for 20 minutes under nitrogen atmosphere to form a blue quantum dot layer; Next, dispensing a zinc oxide (ZnO) solution on the blue quantum dot layer by an inkjet method, and the ZnO solution is dissolved with nano-sized ZnO particles, and the concentration of the ZnO solution is 5 mg/ml, then drying at a temperature of 100-200 degrees Celsius to form a single-layer structure of a first isolation layer having a thickness ranging from 1 nm to 10 nm; Following, repeat the above processes to sequentially form a green light quantum dot layer, a second isolation layer, and a red light quantum dot layer; S5, dispensing an electron transport layer solution on the quantum dot layer, and sintering at 150 degrees Celsius for 20 minutes under nitrogen atmosphere to form an electron transport layer, and the electron transport layer solution may be, for example, a 1,3,5-tris(3-(3-pyridyl)phenyl)benzene solution; and S6, depositing an aluminum metal film as a cathode layer on the electron transport layer by evaporation.

FIG. 3 is a schematic view showing a core-shell structure of a quantum dot according to an embodiment of the present invention, including a nuclear structure 99 composed of at least one of cadmium sulfide, cadmium selenide, cadmium telluride, lead sulfide and lead selenide, and a shell structure 100 composed of zinc sulfide or zinc selenide.

The foregoing quantum dot solution is prepared by dissolving the quantum dots in a non-polar solvent such as n-hexane (polarity 7.3), n-octane (polarity 7.8), cyclohexane (polarity 8.2), toluene (polarity 8.9), or trioxane (polarity 9.3), with a concentration ranging from 10 to 30 mg/ml.

The foregoing isolation layer solution is prepared by dissolving a material such as zinc oxide (ZnO) or titanium dioxide (TiO₂) or tin dioxide (SnO₂) nano-sized particles in one polar solvent such as n-butanol (polarity 11.4), ethanol (polarity 12.7), and methanol (polarity 14.5), with a concentration ranging from 1 to 5 mg/ml.

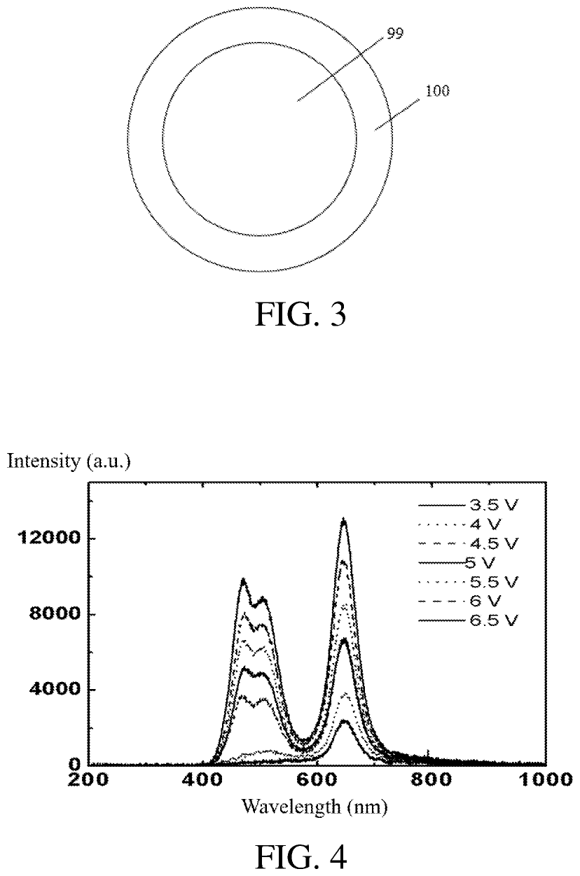

As shown in FIG. 4, an illuminating spectrum of a white light quantum dot light emitting diode device according to an embodiment of the present invention is driven at a voltage ranging from 3.5 to 6.5 V. The emission peaks of the red, green and blue quantum dots are clearly visible in the figure. The device as a whole exhibits white light, and the maximum luminance is greater than 15000 cd/m² at a driving voltage of 3.5V.

The description of the above exemplary embodiments is only for the purpose of understanding the invention. It is to be understood that the present invention is not limited to the disclosed exemplary embodiments. It is obvious to those skilled in the art that the above exemplary embodiments may be modified without departing from the scope and spirit of the present invention.

What is claimed is:

1. A white light quantum dot light emitting diode device comprising:
a substrate;
an anode layer formed on the substrate;
a hole injection layer formed on the anode layer;
a hole transport layer formed on the hole injection layer;
a plurality of quantum dot layers formed on the hole injection layer, wherein the plurality of quantum dot layers comprises a blue quantum dot layer, a green quantum dot layer, and a red light quantum dot layer;
a plurality of insulation layers, each of the insulation layers being formed between any two of the plurality of quantum dot layers;
an electron transport layer formed on the plurality of quantum dot layers; and
a cathode layer formed on the electron transport layer.

2. The white light quantum dot light emitting diode device according to claim 1, wherein the substrate is a glass substrate.

3. The white light quantum dot light emitting diode device according to claim 1, wherein the hole injection layer has a thickness of 10 nm; the hole transport layer has a thickness of 30 nm; and the electron transport layer has a thickness of 50 nm.

4. The white light quantum dot light emitting diode device according to claim 1, wherein the blue quantum dot layer, the green quantum dot layer and the red light quantum dot layer each has a thickness of 30 nm.

5. The white light quantum dot light emitting diode device according to claim 1, wherein the insulation layer is composed of zinc oxide (ZnO) or titanium dioxide (TiO₂) or tin dioxide (SnO₂) particles.

6. The white light quantum dot light emitting diode device according to claim 5, wherein the insulation layer is a single layer structure having a thickness ranging from 1 nm to 10 nm.

7. The white light quantum dot light emitting diode device according to claim 1, wherein the quantum dots are a core-shell structure.

8. The white light quantum dot light emitting diode device according to claim 7, wherein the core structure is composed of at least one of cadmium sulfide, cadmium selenide, cadmium telluride, lead sulfide, and lead selenide; and the shell structure is composed of zinc sulfide or zinc selenide.

9. A method of preparing a white light quantum dot light emitting diode device, comprising:
providing a glass substrate on which an anode layer is formed;
forming a hole injection layer on the anode layer;
forming a hole transport layer on the hole injection layer;
forming a plurality of quantum dot layers and a plurality of insulation layers comprising a blue quantum dot layer, a first insulation layer, a green light quantum dot layer, a second insulation layer, and a red light quantum dot layer on the hole transport layer;
forming an electron transport layer on the plurality of quantum dot layers; and
forming a cathode layer on the electron transport layer.

10. The method of preparing the white light quantum dot light emitting diode device according to claim 9, wherein the insulation layer is formed by any one of spin coating, ink jet, and electroplating.

11. A white light quantum dot light emitting diode device comprising:
a substrate;
an anode layer formed on the substrate;
a hole injection layer having a thickness of 10 nm formed on the anode layer;
a hole transport layer having a thickness of 30 nm formed on the hole injection layer;
a plurality of quantum dot layers formed on the hole injection layer, wherein the plurality of quantum dot layers comprises a blue quantum dot layer, a green quantum dot layer, and a red light quantum dot layer;
a plurality of insulation layers, each of the insulation layers being formed between any two of the plurality of quantum dot layers;
an electron transport layer having a thickness of 50 nm formed on the plurality of quantum dot layers; and
a cathode layer formed on the electron transport layer.

12. The white light quantum dot light emitting diode device according to claim 11, wherein the substrate is a glass substrate.

13. The white light quantum dot light emitting diode device according to claim 11, wherein the insulation layer is composed of zinc oxide (ZnO) or titanium dioxide (TiO₂) or tin dioxide (SnO₂) particles.

14. The white light quantum dot light emitting diode device according to claim 13, wherein the insulation layer is a single layer structure having a thickness ranging from 1 nm to 10 nm.

15. The white light quantum dot light emitting diode device according to claim 11, wherein the quantum dots are a core-shell structure.

16. The white light quantum dot light emitting diode device according to claim 15, wherein the core structure is composed of at least one of cadmium sulfide, cadmium selenide, cadmium telluride, lead sulfide, and lead selenide; and the shell structure is composed of zinc sulfide or zinc selenide.
